(19) United States
(12) Patent Application Publication
(10) Pub. No.: US 2012/0025312 A1
(43) Pub. Date: Feb. 2, 2012

(54) Strain Engineering in Three-Dimensional Transistors Based on a Strained Channel Semiconductor Material

(75) Inventors: Thilo Scheiper, Dresden (DE); Stefan Flachowsky, Dresden (DE); Jan Hoentschel, Dresden (DE)

(73) Assignee: GLOBALFOUNDRIES INC., Grand Cayman (KY)

(21) Appl. No.: 13/164,928

(22) Filed: Jun. 21, 2011

(30) Foreign Application Priority Data
Jul. 30, 2010 (DE) 10 2010 038 742.8

(51) Int. Cl. H01L 27/12; H01L 21/336

(52) U.S. Cl. 257/347; 438/151; 257/E21.409; 257/E27.112

(57) ABSTRACT

In three-dimensional transistor configurations, such as finFETs, at least one surface of the semiconductor fin may be provided with a strained semiconductor material, which may thus have a pronounced uniaxial strain component along the current flow direction. The strained semiconductor material may be provided at any appropriate manufacturing stage, for instance, prior to actually patterning the semiconductor fins and/or after the patterning the semiconductor fins, thereby providing superior performance and flexibility in adjusting the overall characteristics of three-dimensional transistors.

### BACKGROUND OF THE INVENTION

1. Field of the Invention

Generally, the present disclosure relates to the fabrication of highly sophisticated integrated circuits including transistor elements having a non-planar channel architecture.

2. Description of the Related Art

The fabrication of advanced integrated circuits, such as CPUs, storage devices, ASICs (application specific integrated circuits) and the like, requires the formation of a large number of circuit elements on a given chip area according to a specified circuit layout, wherein field effect transistors represent one important type of circuit element that substantially determines performance of the integrated circuits. Generally, a plurality of process technologies are currently practiced, wherein, for many types of complex circuitry including field effect transistors, MOS technology is currently one of the most promising approaches due to the superior characteristics in view of operating speed and/or power consumption and/or cost efficiency. During the fabrication of complex integrated circuits using, for instance, MOS technology, millions of transistors, e.g., N-channel transistors and/or P-channel transistors, are formed on a substrate including a crystalline semiconductor layer. A field effect transistor, irrespective of whether an N-channel transistor or a P-channel transistor is considered, typically comprises so-called PN junctions that are formed by an interface of highly doped regions, referred to as drain and source regions, with a slightly doped or non-doped region, such as a channel region, disposed adjacent to the highly doped regions. In a field effect transistor, the conductivity of the channel region, i.e., the drive current capability of the conductive channel, is controlled by a gate electrode formed adjacent to the channel region and separated therefrom by a thin insulating layer. The conductivity of the channel region, upon formation of a conductive channel due to the application of an appropriate control voltage to the gate electrode, depends on, among other things, the dopant concentration, the mobility of the charge carriers and, for a planar transistor architecture, the distance between the source and drain regions, which is also referred to as channel length.

Presently, the majority of integrated circuits are formed on the basis of silicon due to its substantially unlimited availability, the well-understood characteristics of silicon and related materials and processes and the experience gathered during the past 50 years. Therefore, silicon will likely remain the material of choice for future circuit generations designed for mass products. One reason for the importance of silicon in fabricating semiconductor devices has been the superior characteristics of a silicon/silicon dioxide interface that allows reliable electrical insulation of different regions from each other. The silicon/silicon dioxide interface is stable at high temperatures and, thus, allows the performance of subsequent high temperature processes, as are required, for example, for anneal cycles to activate dopants and to cure crystal damage without sacrificing the electrical characteristics of the interface.

For the reasons pointed out above, in field effect transistors, silicon dioxide is preferably used as a base material for gate insulation layers that separate the gate electrode, frequently comprised of polysilicon or other metal-containing materials, from the silicon channel region. In steadily improving device performance of field effect transistors, the length of the channel region has been continuously decreased to improve switching speed and drive current capability. Since the transistor performance is controlled by, among other things, the voltage supplied to the gate electrode to invert the surface of the channel region to a sufficiently high charge density for providing the desired drive current for a given supply voltage, a certain degree of capacitive coupling, provided by the capacitor formed by the gate electrode, the channel region and the silicon dioxide disposed therebetween, has to be maintained. It turns out that decreasing the channel length for a planar transistor configuration requires an increased capacitive coupling to avoid the so-called short channel behavior during transistor operation. The short channel behavior may lead to an increased leakage current and to a pronounced dependence of the threshold voltage on the channel length. Aggressively scaled planar transistor devices with a relatively low supply voltage and thus reduced threshold voltage may suffer from an exponential increase of the leakage current due to the required enhanced capacitive coupling of the gate electrode to the channel region. Thus, the thickness of the silicon dioxide layer has to be correspondingly decreased to provide the required capacitance between the gate and the channel region. For example, a channel length of approximately 0.08 μm may require a gate dielectric made of silicon dioxide as thin as approximately 1.2 nm. Although usage of high speed transistor elements having an extremely short channel may typically be restricted to high speed applications, whereas transistor elements with a longer channel may be used for less critical applications, such as storage transistor elements, the relatively high leakage current caused by direct tunneling of charge carriers through an ultra-thin silicon dioxide gate insulation layer may reach values for an oxide thickness in the range of 1-2 nm that may no longer be compatible with requirements for many types of circuits.

For these reasons, a plurality of alternative approaches has been developed in an attempt to further enhance performance of planar transistors while avoiding the above-described problems. For instance, replacing silicon dioxide as material for gate insulation layers has been considered, particularly for extremely thin silicon dioxide gate layers. For example, dielectric material with significantly increased dielectric constant may be used, such as hafnium oxide and the like, which, however, may require additional complex processes, thereby contributing to a very complex overall process flow. According to other strategies, performance of planar transistors may be efficiently increased by modifying the lattice structure in silicon-based semiconductor materials. As is well known, tensile or compressive strain may significantly change the charge carrier mobility in silicon-based semiconductor materials, thereby allowing the significantly enhanced performance of planar transistors. For instance, for a standard crystallographic orientation of a silicon-based material, the generation of a tensile strain component along the current flow direction of the channel region of a planar transistor may significantly increase mobility of electrons and, thus, switching speed and drive current capability of the transistor may be increased. On the other hand, for the same standard crystallographic configuration, uniaxial compressive strain in the channel region may enhance mobility of holes, thereby providing the possibility of increasing performance of P-channel transistors. A corresponding strain component may be obtained by providing globally strained semiconductor materials in which corresponding active regions of transistors may be formed. In other well-established process techniques, the strain may be locally generated in the channel region of the transistors by implementing various strain-inducing mechanisms, such as incorporating a strain-inducing semiconductor material in the drain and source regions of N-channel transistors and/or P-channel transistors. For instance, providing a silicon/germanium alloy in the drain and source regions may result, due to the lattice mismatch between the silicon-based material and the silicon/germanium alloy, in a strained configuration, thereby inducing a substantially uniaxial compressive strain component, which may thus increase performance of P-channel transistors. Furthermore, other well-established strain-inducing mechanisms may be applied in the form of highly stressed materials positioned in close proximity to the transistors, thereby also inducing a desired strain component. For this purpose, the interlayer dielectric material provided in the contact level of the transistor elements may be used to induce a desired type of strain.

FIG. 1a schematically illustrates a perspective view of a sophisticated semiconductor device 100 comprising a planar transistor 150, which may be used in complex logic circuits, such as CPUs and the like, in order to obtain a high switching speed and the required drive current, as may be necessary for sophisticated applications. As illustrated, the conventional device 100 may comprise a substrate 101, such as a silicon substrate and the like, possibly in combination with a buried insulating layer 102, thereby providing a silicon-on-insulator (SOI) architecture, which may generally provide certain advantages in terms of switching speed and the like. Moreover, a silicon-based semiconductor layer 103 is formed on the buried insulating layer 102 and may comprise a plurality of “active” regions 103A which are laterally delineated by isolation structures 103B, such as shallow trench isolations and the like. It should be appreciated that an active region is to be understood as a semiconductor region in which appropriate PN junctions are formed or are to be formed for at least one transistor element. In the example shown, the active region 103A comprises a source region 152S and a drain region 153D, which may represent highly doped semiconductor regions so as to provide a moderately high conductivity and to form a PN junction with a channel region 154 positioned between the source region 152S and the drain region 153D. In the case of a P-channel enrichment transistor, drain and source regions 153D, 152S may be P-doped, while the channel region 154 may be slightly N-doped. Thus, for achieving a high drive current of the transistor 150 in the case of a P-channel transistor, the channel region 154 has to be enriched with holes as charge carriers so as to enable a P-conductive path from the source region 1525 to the drain region 153D. For an N-channel transistor, inversely doped drain and source regions and a channel region has to be provided. Furthermore, the transistor 150 comprises a gate electrode structure 151, which may comprise an electrode material 151A that is formed on a gate dielectric material 151B, which thus separates the electrode material 151A from the channel region 154. Furthermore, frequently, a spacer structure 151C may be formed on sidewalls of the electrode material 151A, wherein, for convenience, the spacers 151C are illustrated so as to be transparent in order to not unduly obscure the illustration of the transistor 150.

The interface between the channel region 154 and the gate dielectric material 151B may substantially determine the electronic characteristics of the transistor 150, wherein this interface is provided within a single plane so that the transistor 150 may be considered as a planar transistor device. As previously explained, one important parameter of the transistor 150 is represented by the length of the gate electrode structure 151, which may be understood as the horizontal extension of the electrode material 151A. For instance, in sophisticated applications, the gate length is approximately 50 nm and less, which may thus require a high capacitive coupling of the electrode material 151A to the channel region 154 via the gate dielectric material 151B. Consequently, the thickness and/or the material composition of the gate dielectric material 151B may have to be appropriately selected in order to provide the desired capacitive coupling. Furthermore, the overall drive current of the transistor 150 is also determined by the transistor width, as indicated by 150W, since the width 150W determines the total area available for the charge carrier transport.

Due to the limitations with respect to leakage currents of gate dielectric material and due to the complexity of patterning gate electrode structures and active regions for achieving the required high drive current capability in combination with a high switching speed, additional mechanisms have been implemented in order to create a desired type of strain 156 in the channel region 154. For example, a strain-inducing semiconductor alloy 155 may be incorporated into the drain and source regions 153D, 152S which may have a strained state and which may thus induce the strain 156. Additionally or alternatively to the strain-inducing material 155, the spacer structure 151C may be provided as a highly stressed dielectric material and/or a further material may be formed on the drain and source regions 153D, 152S in a highly stressed state, thereby also inducing a certain degree of strain in the channel region 154. Although these mechanisms may provide a significant enhancement of transistor performance for a given geometric configuration of the transistor 150, upon further device scaling, i.e., upon further reducing the length of the gate electrode structure 151, the efficiency of these mechanisms may significantly decrease, thereby resulting in a less pronounced performance gain.

For these reasons, alternative transistor architectures have been proposed, such as “three-dimensional” architectures, in which a desired channel width and thus transistor width may be obtained at reduced overall lateral dimensions, while at the same time superior controllability of the current flow through the channel region may be achieved. To this end, so-called finFETs have been proposed in which a thin sliver or fin of silicon may be formed above a substrate, wherein, on both sidewalls of the fin and on a top surface thereof, a gate dielectric material and a gate electrode material may be provided, thereby realizing a multiple gate transistor whose total channel region may be fully depleted. Typically, in sophisticated applications, the width of the silicon fins may be on the order of magnitude to 10-20 nm and the height thereof may be on the order of magnitude of 30-40 nm.

Thus, finFET transistor architectures may provide advantages with respect to increasing the effective coupling of the gate electrode to the various channel regions without requiring a corresponding reduction in thickness of the gate dielectric material. Moreover, by providing this non-planar transistor architecture, the effective channel width may also be increased so that, for given overall lateral dimensions of a transistor, an enhanced current drive may be obtained.

FIG. 1b schematically illustrates a perspective view of the semiconductor device 100 which comprises a finFET transistor 120 that is to represent any three-dimensional or “vertical” transistor architecture. As shown, the device 100 comprises the substrate 101 and the insulating layer 102 on which are formed a plurality of semiconductor fins 110, which thus represent the “residues” of a portion of the semiconductor layer 103 (FIG. 1a). Moreover, a gate electrode structure 130 is formed adjacent to a central portion of the semiconductor fins 110 so as to be in contact with corresponding channel regions. It should be appreciated that the gate electrode structure 130 comprises a gate dielectric material formed on sidewalls 110A, 110B and a top surface 110C. According to this configuration, each of the fins 110 comprises a source region 122 and a drain region 123, which may represent respective end portions of the fins 110 and which may thus have an appropriate dopant concentration in order to form PN junctions with the channel region that is covered by the gate electrode structure 130. The semiconductor fins 110 thus enable a controlled current flow along a length direction 110L, wherein the current flow is controlled by the gate electrode structure 130. As previously discussed, for given lateral dimensions of the transistor 120, a significantly increased overall drive current is obtained while the gate electrode structure 130 is less critical, for instance with respect to a thickness of a gate dielectric material.

The semiconductor device 100 comprising the three-dimensional transistor or finFET transistor 120 may be formed on the basis of any appropriate patterning techniques in which the semiconductor fins 110 are formed on the basis of sophisticated lithography and etch techniques in order to etch through the initial semiconductor layer 103 (FIG. 1a) while using the buried insulating layer 102 as an etch stop material. Thereafter, the gate electrode structure 130 is formed, for instance, by forming a desired gate dielectric material, such as a silicon oxide-based material, which may be accomplished by oxidation and/or deposition, followed by the deposition of an electrode material, such as polysilicon and the like. After providing the gate layer stack, appropriate lithography and etch techniques are applied in order to form the gate electrode structure 130 having a desired gate length, as indicated by 130L. Since the entire volume of the channel region may be available for the flow of charge carriers, even a “gate length” of approximately 100 nm may provide a moderately high drive current capability per each semiconductor fin, while, on the other hand, superior controllability may be achieved since the control voltage may act on the channel region from three sides of the semiconductor fin. After providing the gate electrode structure 130, the drain and source regions 122, 123 may be formed on the basis of ion implantation processes and the like in accordance with any appropriate process strategy.

In order to further enhance performance of the finFET transistor 120, it has been proposed to also apply strain-inducing mechanisms, similarly as are described with reference to the planar transistor 150 of FIG. 1a, for instance, by providing highly stressed dielectric materials close to the transistor configuration, by incorporating strain-inducing semiconductor materials in the semiconductor fins 110 and the like. Due to the complex three-dimensional configuration of the transistor 120, however, and due to the overall reduced dimensions, the corresponding strain-inducing mechanisms may also be less effective, while at the same time very complex additional processes may have to be implemented into the overall process flow. For example, the deposition of a highly stressed dielectric material between and above the semiconductor fins 110 may impose significant restrictions with respect to gap filling capabilities of the corresponding process techniques, while the incorporation of a strain-inducing semiconductor alloy, such as a silicon/germanium alloy, into the drain and source areas of the semiconductor fins 110 may be less efficient due to the moderately reduced surface area of the semiconductor fins. Similarly, upon re-growing a semiconductor material between drain and source end portions of the semiconductor fins 110 in order to form a continuous drain and source region, the incorporation of a strain-inducing semiconductor material may be less effective, since any additional strain-inducing semiconductor material may not efficiently act on the central portions of the semiconductor fins 110.

The present disclosure is directed to various methods and devices that may avoid, or at least reduce, the effects of one or more of the problems identified above.

### SUMMARY OF THE INVENTION

The following presents a simplified summary of the invention in order to provide a basic understanding of some aspects of the invention. This summary is not an exhaustive overview of the invention. It is not intended to identify key or critical elements of the invention or to delineate the scope of the invention. Its sole purpose is to present some concepts in a simplified form as a prelude to the more detailed description that is discussed later.

Generally, the present disclosure provides semiconductor devices and manufacturing techniques in which a strain-inducing mechanism may be efficiently implemented on the basis of a strained semiconductor material, which may be provided at least on one surface of a semiconductor fin or any elongated body, which may be used in a non-planar transistor architecture. The strained semiconductor material may be provided at least in a portion of the semiconductor fin that corresponds to the channel region, thereby providing at least advantageous strain conditions within the strained semiconductor channel material, which may thus result in superior charge carrier mobility within the channel region formed in the semiconductor fin or in the elongated semiconductor body. It is well known that a strained semiconductor material may be efficiently formed on a crystalline base material when the base material and the grown semiconductor material may have a certain mismatch of their natural lattice constants, which may thus result in an adoption of the lattice constant of the base material by the regrown semiconductor material, which may thus be provided in a strained state. For example, a silicon/germanium material having a germanium concentration of up to 35 atomic percent or higher may be efficiently grown on a silicon base material wherein the silicon/germanium material may thus be grown with a lattice constant that is substantially determined by the lattice constant of silicon, which is less than the lattice constant of a silicon/germanium mixture due to the increased covalent radius of the germanium atoms compared to the silicon atoms. Consequently, a strained state may be obtained within the silicon/germanium layer, which may also significantly affect the electronic characteristics of this material. It has been recognized that an appropriate selection of the ratio of length and width of the strained semiconductor material may result in a pronounced desired uniaxial strain component in the strained semiconductor material along the current flow direction, while the strain component perpendicular to this direction may be significantly reduced, thereby achieving the desired strain conditions for enhancing the charge carrier mobility within the channel region of the semiconductor fin under consideration. Therefore, by providing an additional semiconductor material in the semiconductor fins, other electronic characteristics may also be efficiently adjusted, such as the threshold voltage of the transistors, for instance in combination with specific gate dielectric materials and the like, thereby providing superior flexibility in adjusting overall transistor characteristics. In some illustrative embodiments disclosed herein, a strain-inducing semiconductor material may be formed on any surface area of the semiconductor fin, thereby even further enhancing the overall strain component in the channel region of the fin.

One illustrative method disclosed herein comprises providing a strained semiconductor channel material on a semiconductor fin that is formed above a substrate of a semiconductor device, wherein the semiconductor fin has a length and a width that result in a substantially uniaxial strain of the semiconductor channel material oriented along a length of the semiconductor fin. The method further comprises forming a gate electrode structure on at least a central portion of the semiconductor fin, wherein the gate electrode structure is configured to control a channel region in the semiconductor fin. Additionally, the method comprises forming drain and source areas adjacent to the channel region.

A further illustrative method disclosed herein relates to forming a transistor of a semiconductor device. The method comprises forming an elongated semiconductor body from a semiconductor base material. Moreover, the method comprises providing a strained semiconductor material on at least one surface of the elongated semiconductor body. Furthermore, the method comprises forming a gate electrode structure above at least a portion of the elongated semiconductor body, wherein the gate electrode structure comprises a gate electrode for controlling a channel region of the elongated semiconductor body.

One illustrative semiconductor device disclosed herein comprises a semiconductor fin that comprises a semiconductor base material and a strained semiconductor channel material that is formed at least on one surface of the semiconductor fin. The semiconductor device further comprises a gate electrode structure formed adjacent to and around at least a portion of the semiconductor fin, wherein the gate electrode structure is configured to control a current flow through the at least a portion of the semiconductor fin.

### BRIEF DESCRIPTION OF THE DRAWINGS

The disclosure may be understood by reference to the following description taken in conjunction with the accompanying drawings, in which like reference numerals identify like elements, and in which:

FIG. 1a schematically illustrates a perspective view of a planar transistor element including a strain-inducing mechanism;

FIG. 1b schematically illustrates a perspective view of a three-dimensional transistor, such as a finFET, which comprises a plurality of semiconductor fins that are formed in accordance with conventional process strategies;

FIG. 2a schematically illustrates a perspective view of a three-dimensional transistor comprising a plurality of semiconductor fins having formed thereon a strained channel material, according to illustrative embodiments;

FIG. 2b schematically illustrates a cross-sectional view of the device of FIG. 2a;

FIGS. 2c and 2d schematically illustrate a top view and a cross-sectional view, respectively, during a process sequence for forming the strained semiconductor channel region on a dedicated active region, according to illustrative embodiments;

FIG. 2e schematically illustrates the crystalline structure of the semiconductor base material and the channel material;

FIGS. 2f-2h schematically illustrate top views of a semiconductor base material comprising a strained semiconductor material, wherein the strain conditions are illustrated for different ratios of length to width, according to illustrative embodiments;

FIGS. 2i and 2j schematically illustrate graphs representing the change in charge carrier mobility versus length (FIG. 2i) and versus width (FIG. 2j) for some examples of a device architecture;

FIG. 2k schematically illustrates a semiconductor fin that is formed in accordance with the above criteria for obtaining a pronounced uniaxial strain component, according to illustrative embodiments;

FIG. 2l schematically illustrates a top view of a plurality of semiconductor fins and a corresponding gate electrode structure which may have an appropriately selected length in order to provide superior strain conditions, according to illustrative embodiments;

FIG. 2m schematically illustrates a top view of a finFET transistor, wherein the semiconductor fins are provided under the gate electrode structure and connect to continual drain and source regions, according to illustrative embodiments;

FIGS. 2n and 2o schematically illustrate the semiconductor device during various manufacturing stages in forming semiconductor fins comprising different types of strain-inducing materials for different transistor types, according to illustrative embodiments; and

FIG. 2p schematically illustrates a perspective view of semiconductor fins, wherein each surface of a semiconductor base material of the semiconductor fin may be covered by a strain-inducing semiconductor material, according to still further illustrative embodiments.

While the subject matter disclosed herein is susceptible to various modifications and alternative forms, specific embodiments thereof have been shown by way of example in the drawings and are herein described in detail. It should be understood, however, that the description herein of specific embodiments is not intended to limit the invention to the particular forms disclosed, but on the contrary, the intention is to cover all modifications, equivalents, and alternatives falling within the spirit and scope of the invention as defined by the appended claims.

### DETAILED DESCRIPTION

Various illustrative embodiments of the invention are described below. In the interest of clarity, not all features of an actual implementation are described in this specification. It will of course be appreciated that in the development of any such actual embodiment, numerous implementation-specific decisions must be made to achieve the developers' specific goals, such as compliance with system-related and business-related constraints, which will vary from one implementation to another. Moreover, it will be appreciated that such a development effort might be complex and time-consuming, but would nevertheless be a routine undertaking for those of ordinary skill in the art having the benefit of this disclosure.

The present subject matter will now be described with reference to the attached figures. Various structures, systems and devices are schematically depicted in the drawings for purposes of explanation only and so as to not obscure the present disclosure with details that are well known to those skilled in the art. Nevertheless, the attached drawings are included to describe and explain illustrative examples of the present disclosure. The words and phrases used herein should be understood and interpreted to have a meaning consistent with the understanding of those words and phrases by those skilled in the relevant art. No special definition of a term or phrase, i.e., a definition that is different from the ordinary and customary meaning as understood by those skilled in the art, is intended to be implied by consistent usage of the term or phrase herein. To the extent that a term or phrase is intended to have a special meaning, i.e., a meaning other than that understood by skilled artisans, such a special definition will be expressly set forth in the specification in a definitional manner that directly and unequivocally provides the special definition for the term or phrase.

Generally, the present disclosure provides efficient strain-inducing mechanisms by providing a strained semiconductor material at least in the channel portion of semiconductor fins, which may also be referred to herein as elongated semiconductor bodies, wherein the geometric configuration of the semiconductor fins may be taken advantage of in order to provide a significant uniaxial strain component in the strained semiconductor material. Consequently, a high strain may be directly provided in the channel region of the semiconductor fins, which may provide superior overall transistor performance compared to conventional strain-inducing mechanisms which may be based on embedded strain-inducing semiconductor alloys which, however, may not directly act on the channel region, as is previously discussed with reference to the three-dimensional transistor 120. In some illustrative embodiments, the strained semiconductor material may be provided on a top surface of the semiconductor base material in an early manufacturing stage so that the resulting layer stack may be efficiently patterned in accordance with well-established process strategies without requiring significant modifications. In other illustrative embodiments disclosed herein, a strained semiconductor material may be provided on any exposed surface area of a semiconductor fin formed from a base material, thereby enabling superior strain conditions and also providing desired electronic characteristics, for instance, in terms of adjusting a threshold voltage and the like. For example, an efficient band gap adjustment may be accomplished on the basis of the strained channel material in combination, for instance, with sophisticated gate dielectric materials, such as high-k materials, which may frequently be used in sophisticated applications in order to reduce gate leakage currents.

In other illustrative embodiments, different types of strained materials may be applied, for instance for different types of transistors and the like, in order to individually adjust performance of transistors, such as P-channel transistors and N-channel transistors. In other cases, the uniaxial strain component may be combined with an appropriate selection of the crystallographic configuration of the semiconductor fins, for instance by orienting the length direction thereof with respect to a preferred crystal axis, such as a <100> equivalent axis or a <110> equivalent axis, which may enable an increase in performance for different types of transistors based on the same uniaxial strain component.

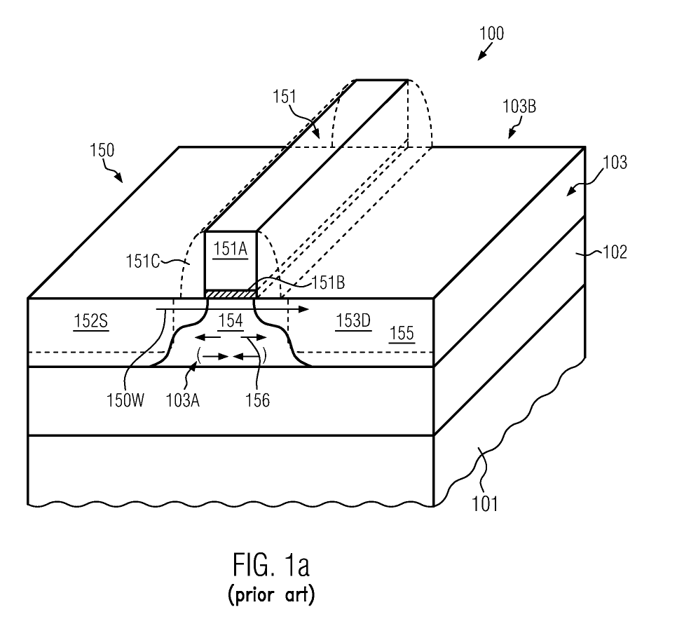

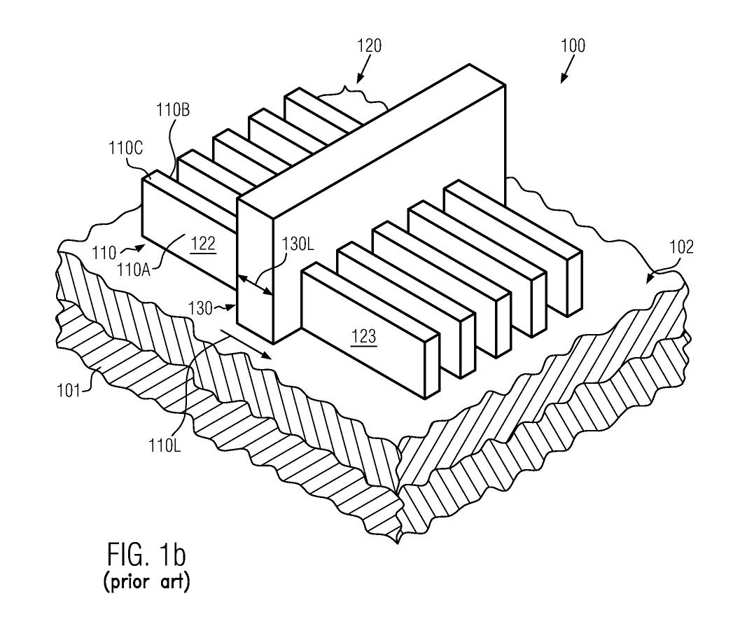

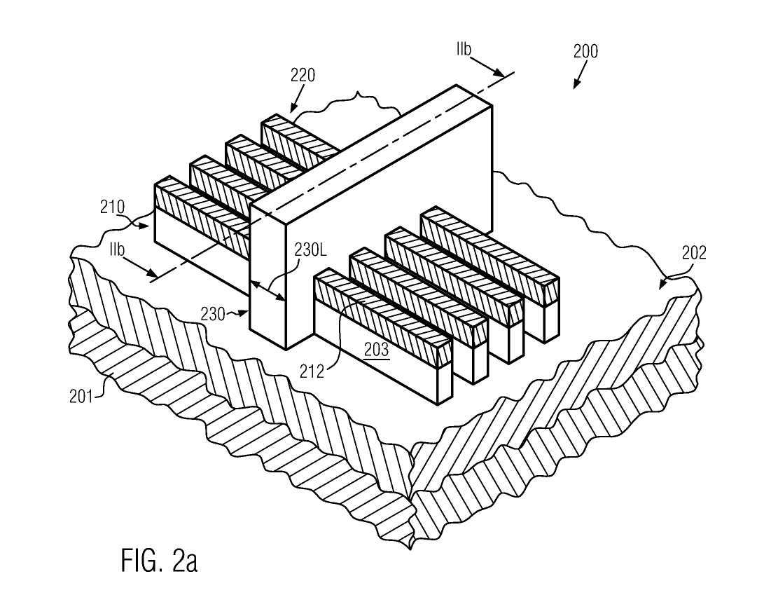

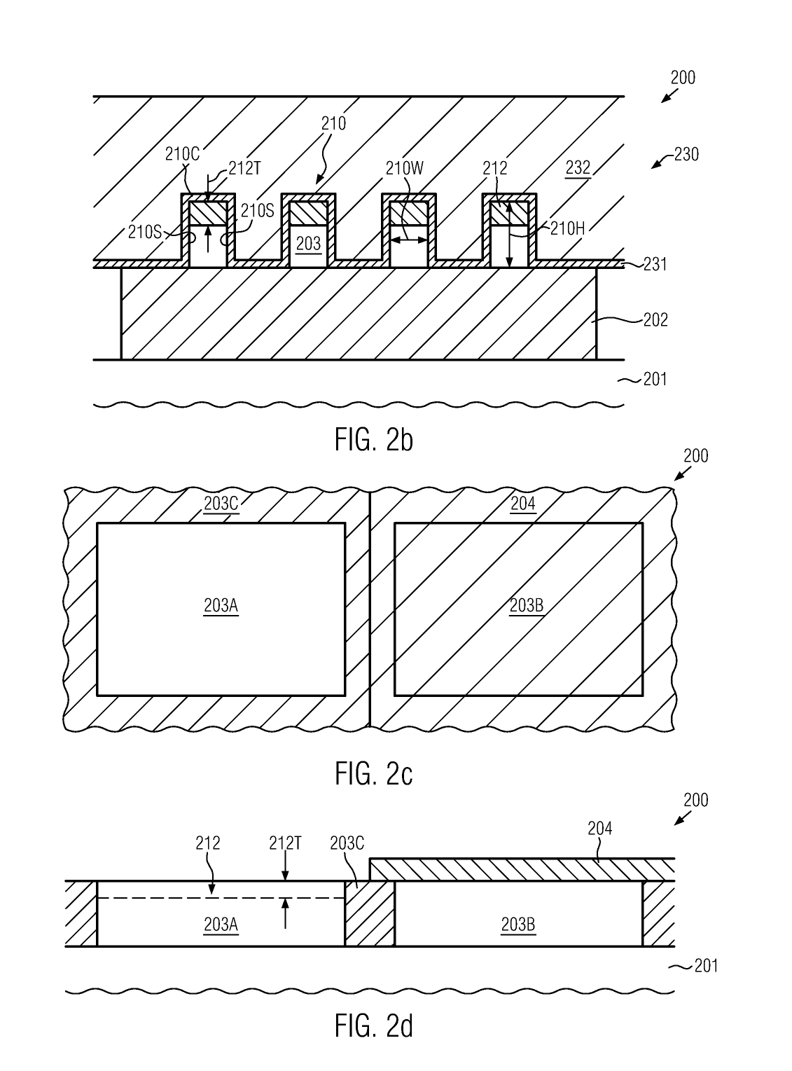

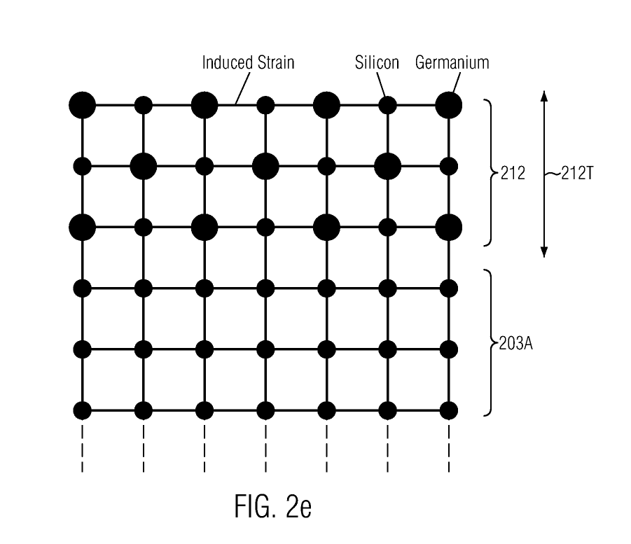

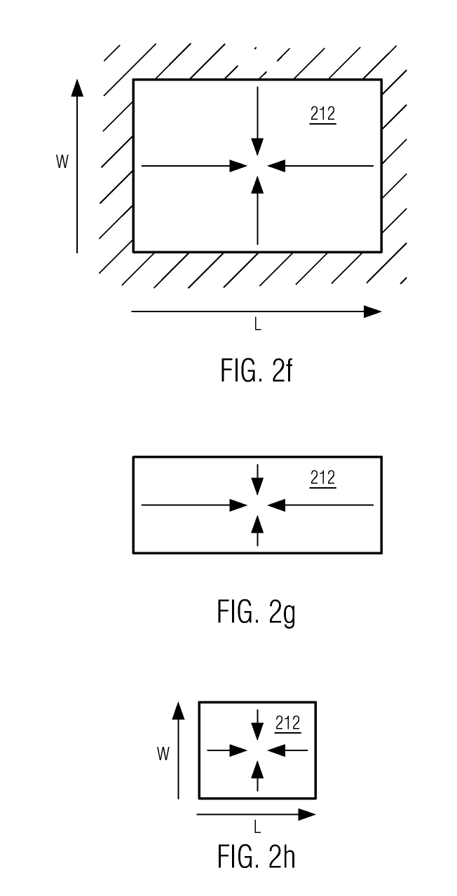

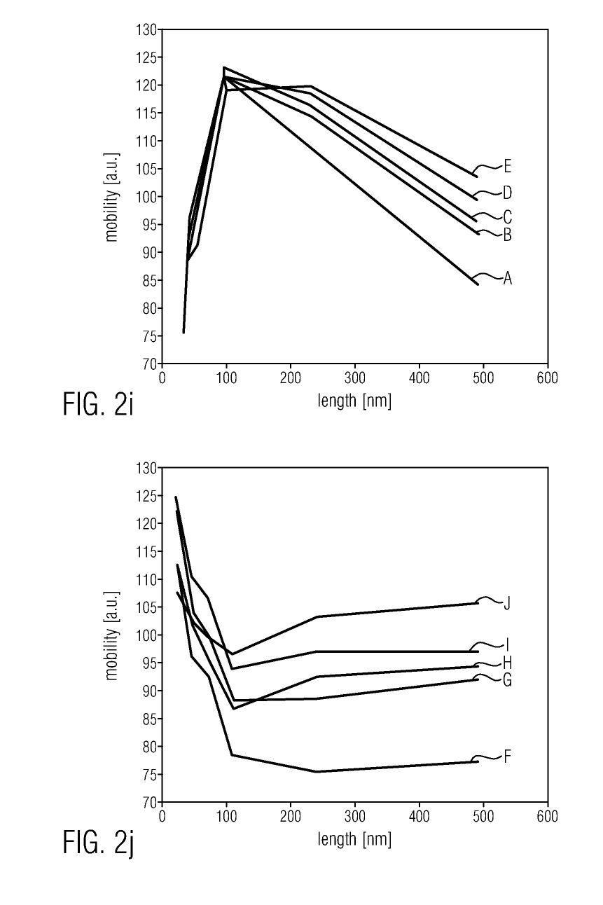

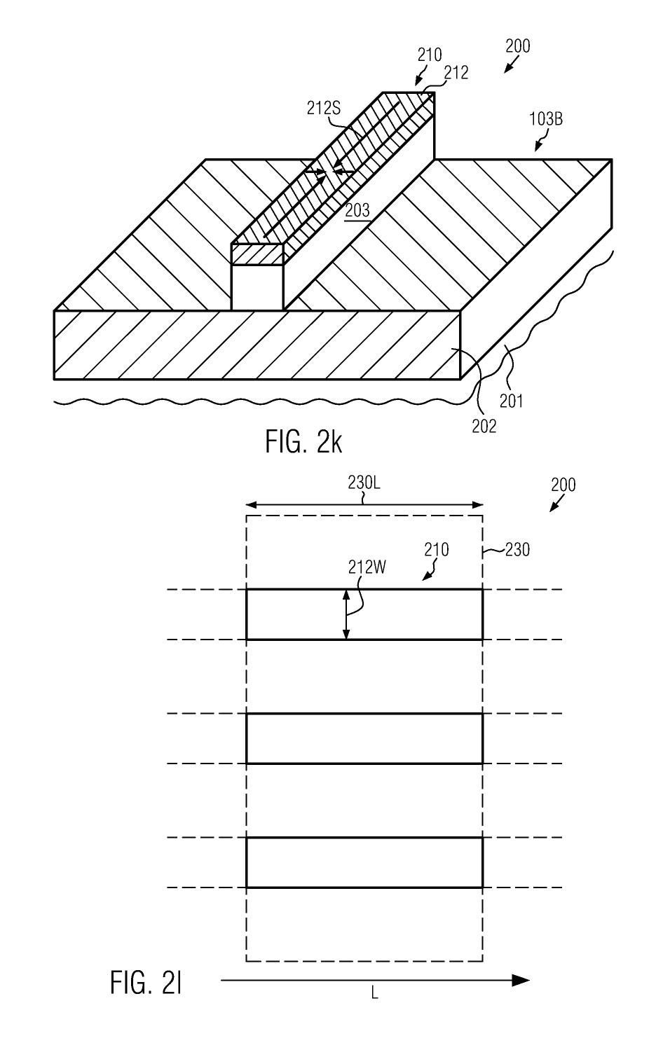

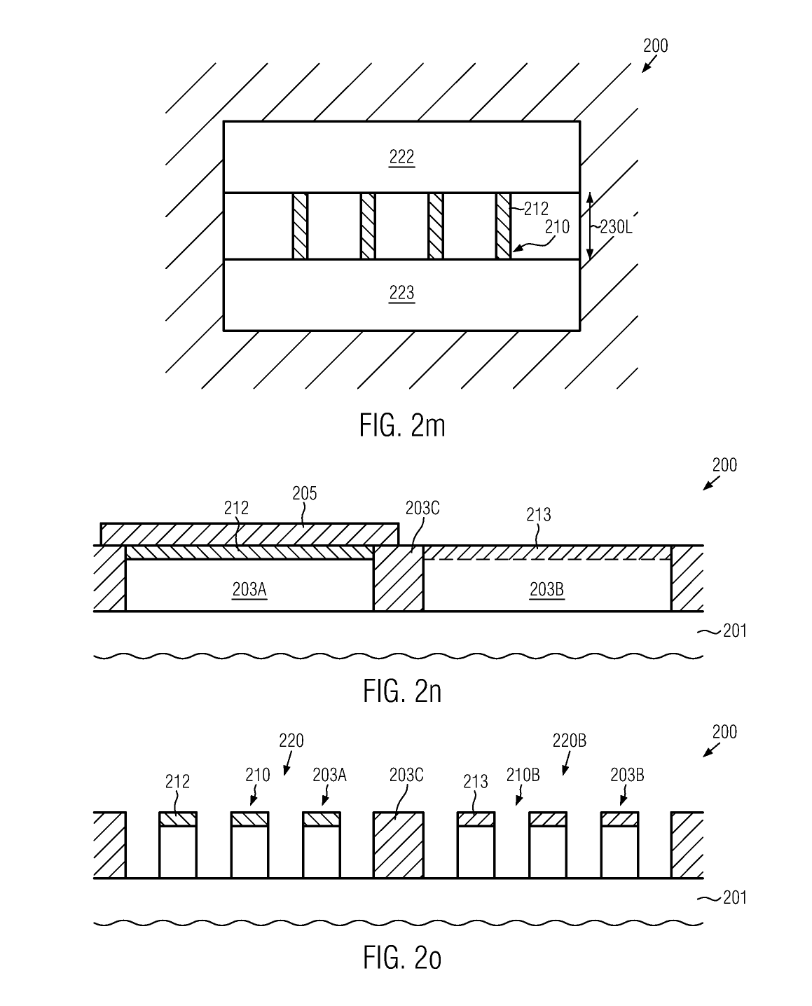

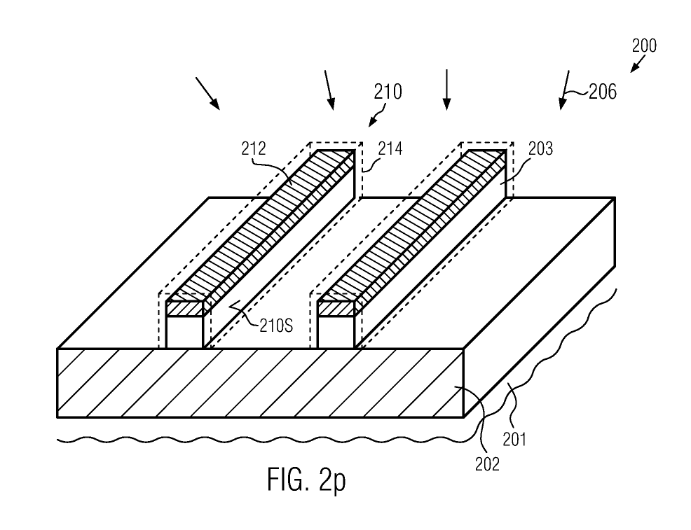

With reference to FIGS. 2a-2p, further illustrative embodiments will now be described in more detail, wherein reference may also be made to FIGS. 1a-1b, if appropriate.

FIG. 2a schematically illustrates a perspective view of a semiconductor device 200, which may comprise a three-dimensional or a non-planar transistor 220. The transistor 220 may also be referred to as a finFET transistor, as is also discussed above. The transistor 220 may be formed above a substrate 201, such as a silicon substrate or any other appropriate carrier material above which may be provided a material layer 202, in or above which the transistor 220 may be implemented. For example, the material layer 202 may represent an insulating material, for instance in the form of a silicon dioxide material, a silicon nitride material and the like. Thus, the layer 202 may represent a “buried” insulating layer in an initial manufacturing stage of the substrate 200, thereby providing an SOI architecture of the transistor 220. In other cases, the material layer 202 may be comprised of a semiconductor material, thereby forming a bulk configuration with a crystalline semiconductor material of the substrate 201. In the manufacturing stage shown, the transistor 220 may comprise a plurality of semiconductor fins 210, which may also be considered as elongated semiconductor bodies having appropriate lateral dimensions and a height so as to comply with the overall transistor characteristics and also comply with geometrical configurations as required for obtaining a desired high strain component, as will be described later on in more detail. The semiconductor fins 210 may comprise a semiconductor base material 203, such as a silicon material, in combination with a strained semiconductor material, such as a silicon/germanium material, a silicon/carbon material and the like, as required for obtaining a desired strain component. In the embodiment shown, the strained semiconductor material 212 may be formed on top of the base material 203, while, in other cases, any exposed surface areas of a base material may be covered by a strained semiconductor material, as will be described later on in more detail. Furthermore, a gate electrode structure 230 may be formed above and in contact with at least a central portion of the semiconductor fins 210, wherein the gate electrode structure 230 may comprise an appropriate dielectric material in combination with an electrode material, as described below with reference to FIG. 2b. Moreover, as illustrated, the gate electrode structure 230 may have a specified extension along a length direction of the semiconductor fins 210, wherein the corresponding lateral dimension is indicated by 230L and is also referred to herein as a gate length.

FIG. 2b schematically illustrates a cross-sectional view of the device 200 along the line IIb as shown in FIG. 2a. As illustrated, the semiconductor fins 210 may have a width 210W which may be in the range of approximately 10-50 nm, depending on the overall requirements of the device 200. Moreover, a height 210H may be 20-100 nm, depending on the overall electronic characteristics of the semiconductor fins 210. Furthermore, the strain-inducing material 212 may be provided on top of the semiconductor base material 203 with a thickness 212T which may range from 5-12 nm in sophisticated applications, while, in other illustrative embodiments, a thickness of greater than 12 nm may be applied, while, at least in some surface areas of the material 203, a thickness of less than 5 nm may be applied, as will be discussed later on in more detail. Furthermore, as illustrated, the gate electrode structure 230 may comprise a gate dielectric material 231, for instance provided in the form of a silicon dioxide-based material, a silicon nitride material, a silicon oxynitride material, or any of these materials in combination with a high-k dielectric material, which is to be understood as a dielectric material having a dielectric constant of 10.0 or higher, for instance in the form of hafnium oxide, hafnium silicon oxide, zirconium oxide and the like. In other cases, the dielectric material 231 may represent any high-k dielectric material without requiring any additional conventional dielectric material, such as silicon dioxide and the like. Moreover, an electrode material 232 may be provided, for instance in the form of a polysilicon material and the like, while, in sophisticated applications, in addition or alternatively to a semiconductor material, a metal-containing material may be provided, for instance in the form of titanium nitride, tantalum, tantalum nitride, aluminum and the like. Thus, sidewall surface areas 210S of the semiconductor fins 210 and a top surface 210C may be in direct contact with gate dielectric material 231, which may have a substantially uniform thickness at any of these surface areas so that control of a current flow through the semiconductor fins 210 may be efficiently effected via all of these surface areas. Consequently, the portion of the semiconductor fin 210 that is in direct contact with the gate electrode structure 230, i.e., with the gate dielectric material 231 and the electrode material 232, may represent a channel region, the conductivity of which may be determined by the electronic characteristics of the semiconductor base material 203 and of the strained channel material 212. Consequently, by appropriately increasing the conductivity of the material 212, for instance by providing an increased uniaxial strain component along the current flow direction, i.e., in FIG. 2b, the direction perpendicular to the drawing plane of FIG. 2b, the total conductivity of the channel region within the semiconductor fins 210 may be increased, thereby also providing superior transistor performance, as is also discussed above.

The semiconductor device 200 as shown in FIGS. 2a and 2b may be formed on the basis of appropriate process strategies for patterning the semiconductor fins 210 and providing appropriate gate materials for the structure 230 and patterning the same, as is for instance also discussed above. The strained semiconductor material 212 may be formed on the basis of process techniques as will be described in more detail with reference to FIGS. 2c-2h.

FIG. 2c schematically illustrates a top view of the semiconductor device 200 in an early manufacturing stage. As illustrated, a plurality of active regions 203A, 203B may be laterally delineated by an isolation region 203C. In this respect, an active region is to be understood as a semiconductor region, which may generally correspond to the lateral size of a transistor to be formed on the basis of a plurality of semiconductor fins, at least a portion of which may be formed from the semiconductor material of the corresponding active region. Consequently, at least after patterning a portion of the corresponding active region into one or more semiconductor fins or elongated semiconductor bodies, appropriate dopant species may be incorporated so as to form corresponding PN junctions as required for appropriately controlling the current flow through a channel region, as explained above. For example, the active region 203A may represent a semiconductor material which may be used for semiconductor fins that may receive the strained semiconductor material 212 (FIG. 2b), while the active region 203B may correspond to a transistor element in which the deposition of the strained semiconductor material is not required. To this end, the active region 203B and a corresponding portion of the isolation region 203C may be covered by a mask 204.

FIG. 2d schematically illustrates a cross-sectional view of the semiconductor device 200 as shown in FIG. 2c. As illustrated, the mask 204 may cover at least the active region 203B, while the active region 203A may be exposed, wherein, in some illustrative embodiments, a recess may be formed therein in order to receive the strained semiconductor material 212 in a subsequent selective epitaxial growth process. To this end, any appropriate etch strategy may be applied, for instance wet chemical etch recipes, plasma assisted etch recipes, in order to remove a portion of the active region 203A, for instance in accordance with the thickness 212T of the strained semiconductor material to be formed in or above the active region 203A. It should be appreciated that a plurality of selective epitaxial growth techniques are well established and may be used for depositing semiconductor materials, such as silicon/germanium, silicon/carbon and the like. During a selective deposition process, the deposition of a semiconductor material may be restricted to exposed surface areas of a crystalline base material, such as the active region 203A, while a significantly material deposition on dielectric surface areas may be suppressed.

FIG. 2e schematically illustrates a cross-sectional view of the semiconductor material obtained after the selective epitaxial growth of the strained semiconductor material 212. As shown, the material of the layer 212 may take on substantially the same crystallographic configuration as the base material 203A, which may represent a silicon material, for instance formed on an insulating layer or on a crystalline substrate material, as discussed above. Consequently, since generally the silicon/germanium material may have a greater lattice constant when provided in a non-strained state, forcing the material 212 to grow on the basis of the lattice constant of the underlying silicon material 203A may result in a significant strained state of the material 212, which in turn may significantly affect the overall electronic characteristics, such as the mobility of holes and electrons, which may also depend on specific crystallographic directions. As previously explained, a compressive strain oriented along a current flow direction in a silicon material or a silicon/germanium material may significantly increase the mobility of holes, i.e., the majority charge carriers, thereby providing superior conductivity. On the other hand, a compressive strain in a direction perpendicular to the current flow direction may reduce the charge carrier mobility and may thus negatively affect the overall conductivity.

FIG. 2f schematically illustrates the situation in the material 212, wherein the material 212 may have moderately large dimensions in a length direction, indicated by L, and in a width direction, indicated by W. Due to the strained growth of the material 212, as described with reference to FIG. 2e, a strain may be present in any lateral direction within the material 212, which may also be referred to as biaxial strain. For example, in the width direction and the length direction, a corresponding pronounced compressive strain component may be present. It should be appreciated, however, that a corresponding high compressive strain component exists in any lateral direction within the layer 212. It has been recognized that reducing the dimensions along the width direction may also result in a significant relaxation of the corresponding strain component, however, without unduly affecting the strain component in the length direction.

FIG. 2g schematically illustrates a corresponding geometric configuration of the layer 212, wherein a significant reduction of the lateral size in the width direction may result in a corresponding reduced compressive strain component, while on the other hand a desired high strain component in the length direction may still be present.

FIG. 2h schematically illustrates the situation for the layer 212 when also reducing the length dimension, thereby also resulting in a significant reduction of the strain component in this direction. Consequently, by using a geometry for the layer 212 as shown in FIG. 2g, a significant strain component may be preserved in the layer 212, while the orthogonal strain component may be significantly reduced.

FIG. 2i schematically illustrates mobility of a P-channel transistor in a planar configuration, for instance as previously explained with reference to FIG. 1a, wherein additionally a channel silicon/germanium material may be provided, for instance in addition to any other strain-inducing mechanisms, as is also discussed above. The horizontal axis represents the current flow direction and thus the length of the planar transistor of FIG. 1a. Moreover, the behavior of the mobility for five different thickness values of 6, 7, 8, 9 and 10 nm for a corresponding channel material is illustrated and represented by the corresponding curves A, B, C, D and E. For example, for a length of approximately 40 nm, the situation may be substantially represented by FIG. 2h, by increasing the length of the transistor, the mobility may also increase, since an advantageous uniaxial strain component along the length direction may be obtained, as is for instance shown in FIG. 2g. For example, at approximately 100 nm, a maximum mobility may be obtained, since uniaxial strain components of the channel material in combination with any other strain-inducing mechanisms may result in a maximum. Upon further increase of the length, the uniaxial strain component may further be increased, thereby resulting in a reduction of the mobility, since any other strain mechanisms may also drop in efficiency.

Similarly, FIG. 2j schematically illustrates the situation when varying the width of the planar transistor configuration. As expected, upon using a reduced width, for instance as shown in FIG. 2g, a desired high mobility may be obtained for a given transistor length due to a moderately high uniaxial strain component along the current flow direction. On increasing the width, an increasing degree of strain relaxation may be observed, as indicated by the curves F, G, H, I and J, which may finally result in a substantially constant behavior, since maximum strain relaxation may be achieved, while also any other strain-inducing mechanisms may have a substantially constant effect.

Consequently, by using a strained channel material in a transistor configuration which may have per se a superior length to width ratio, an efficient uniaxial strain component along the current flow direction may be obtained.

FIG. 2k schematically illustrates the situation for the semiconductor fin 210 wherein the strained channel semiconductor material 212 may be formed on the base material 203, wherein, due to the geometry of the semiconductor fin 210, a pronounced uniaxial strain component 212S may be obtained, for instance in the form of a compressive strain component, if a silicon/germanium material is formed on a silicon base material. It should be appreciated that the superior elongated geometry of the semiconductor fin 210 may also be obtained in a channel portion thereof, since typically the gate electrode structure, such as the structure 230 as previously described, for instance, with reference to FIG. 2a, may have a length of several nanometers, which may also include any spacer elements and the like, so that generally the portion of the semiconductor fin 210 covered by the gate electrode structure may also have an elongated geometry and may thus provide superior strain conditions.

FIG. 2l schematically illustrates a top view of the semiconductor device 200 wherein the plurality of fins 210 may have a superior elongated configuration “within” the gate electrode structure 230. That is, the length of the relevant portion of the semiconductor fins 210, indicated by the gate length 230L, may be greater than a width of the fins 210, as indicated by 212W, so that a pronounced strain component may be obtained along the length direction L, as discussed above. Consequently, upon forming the strained semiconductor material 212, as, for instance, explained with reference to FIGS. 2c, 2d and 2e, and by using appropriate lateral dimensions, as indicated in FIG. 2l by the gate length 230L and 212W, the active region 203A (FIG. 2c) may be patterned so as to obtain the semiconductor fins 210 as shown in FIG. 2l having the desired length to width ratio. To this end, any appropriate process strategies may be used, for instance also described with reference to the semiconductor device 100.

FIG. 2m schematically illustrates a top view of the semiconductor device 200 according to further illustrative embodiments in which the semiconductor fins 210 may be formed so as to substantially correspond in length to the gate length 230L, while corresponding drain and source regions 223, 222 may be provided in the form of continuous semiconductor areas. The configuration as shown in FIG. 2m may be formed on the basis of any appropriate process strategy in which the fins 210 may be formed within a semiconductor material without requiring a patterning of the drain and source regions 223, 222, thereby avoiding any subsequent complex selective epitaxial growth process for re-growing a desired semiconductor material in order to provide continuous drain and source regions for the plurality of semiconductor fins 210. Also in this case, the fins 210 may have an appropriate length, indicated by the gate length 230L, in order to provide a desired high uniaxial strain component in the material 212, as discussed above. It should be appreciated that the material 212 may also be provided on the drain and source regions 223, 222, wherein, however, a biaxial strain component may not negatively affect the overall transistor characteristics since the corresponding strain may be efficiently relaxed, for instance, upon incorporating the drain and source dopant species on the basis of implantation techniques, while, however, the semiconductor fins 210 may be efficiently protected by the corresponding gate electrode structure.

FIG. 2n schematically illustrates a cross-sectional view of the semiconductor device 200 according to further illustrative embodiments in which the strained channel material 212 may be formed on the active region 203A, as previously discussed, while also a further strained semiconductor material 213 may be formed on the active region 203B in order to provide a corresponding three-dimensional transistor with appropriate strain conditions. To this end, the active region 203A comprising the strained material 212 may be masked by any appropriate mask material 205, such as silicon dioxide, silicon nitride and the like. Based on the mask 205, the material 213 may be provided on the basis of any selective epitaxial growth techniques, wherein the material 213 may differ from the material 212, at least in its material composition. For example, the material 213 may be provided as a semiconductor material having a different type of internal strain, such as a tensile strain, when the material 212 may be provided with a compressive strain. In other cases, the materials 212 and 213 may be provided with the same type of strain, however, with a different magnitude, while also, if desired, material composition may be different in the material 213 in order to adjust the overall electronic characteristics differently with respect to the active region 203A.

FIG. 2o schematically illustrates the semiconductor device 200 in a further advanced manufacturing stage. As shown, the semiconductor fins 210 may be provided with the strained material 212 on the basis of the material of the active region 203A, while semiconductor fins 210B may be formed on the basis of the active region 203B and may comprise the strained semiconductor material 213. The semiconductor fins 210, 210B may be formed on the basis of any appropriate patterning strategy, as described above. Thereafter, the processing may be continued by forming corresponding gate electrode structures, for instance by depositing a gate dielectric material and an electrode material and patterning the same using any appropriate lithography and etch strategies. Consequently, the transistor 220 may be formed on the basis of the strained material 212, while a transistor 220B may be formed on the basis of the strained material 213, which may differ in type of strain, magnitude of strain and electronic characteristics. Thus, a high degree of flexibility in appropriately adjusting the overall transistor characteristics may be obtained on the basis of the materials 212, 213, which may be provided in an early manufacturing stage, substantially without affecting the further processing, i.e., the patterning of the semiconductor fins 210, 210B and the formation of an appropriate gate electrode structure.

FIG. 2p schematically illustrates the semiconductor device 200 according to further illustrative embodiments in which a strained semiconductor material 214 may be provided in an advanced manufacturing stage. As illustrated, the semiconductor fins 210 may be provided with appropriate lateral dimensions and may be comprised of the semiconductor base material 203, as discussed above. Moreover, the semiconductor fins 210 may be formed on the dielectric material layer 202, thereby providing an SOI configuration. In this manufacturing stage, the device 200 may be exposed to a selective deposition ambient 206 in order to selectively deposit the material 214 on exposed semiconductor surface areas. Consequently, the material 214 may be grown on any exposed surface areas of the base material 203, thereby covering the sidewall surface areas 2105 thereof. In some illustrative embodiments, the material 214 may also be grown on a top surface of the base material 203, while, in other embodiments, as shown in FIG. 2p, a strain-inducing material may already have been formed on top of the base material 203, for instance in the form of the material 212, as previously discussed. The material 214 may be provided with a layer thickness of, for instance, one nanometer to several nanometers, depending on the finally desired width and height of the semiconductor fins 210. It should be appreciated that the sidewall surface areas 210S may also provide a desired length to width ratio so that a pronounced strain component may be obtained in the material 214 along the length direction of the semiconductor fins 210. Consequently, upon forming the material 214 after patterning of the semiconductor fins 210, any exposed surface areas of the base material 203 may be brought into contact with a strained semiconductor material, thereby providing, in total, an increased amount of strained semiconductor material, which may thus also result in superior mobility of the corresponding charge carriers. Furthermore, by adding the material 214 in a late manufacturing stage, i.e., after patterning of the semiconductor fins 210, also specific electronic characteristics of the transistors may be adjusted in a more uniform manner, for instance in terms of threshold voltage and the like. For example, a more uniform response of the semiconductor fin, i.e., of a channel portion thereof, with respect to any applied control voltage may be achieved by providing a substantially uniform layer thickness above any exposed surface area of the base material 203. For example, if a specific energy level configuration may be required at an interface between the semiconductor fin 210 and a gate dielectric material, the provision of the material 214 at any exposed surface area may thus result in a very uniform adaptation of the electronic characteristics at the interface to the gate electrode structure.

In other cases, the material 212 may be provided in an early manufacturing stage, as previously discussed, and the material 214 provided after the patterning of the semiconductor fins 210 may be used as a further mechanism for adjusting the overall electronic characteristics, for instance, by adjusting the final strain component, adjusting the overall electronic characteristics and the like.

After the deposition of the material 214, which may be substantially restricted to the semiconductor fins 210 due to the selective nature of the deposition process 206, the further processing may be continued by depositing a dielectric material and an electrode material of a gate electrode structure. Consequently, also in this case, well-established process techniques may be applied so as to adjust the electronic characteristics of the semiconductor fins 210, without requiring significant modifications with respect to any other well-established process strategies, which are applied for forming conventional three-dimensional transistors.

As a result, the present disclosure provides manufacturing techniques and semiconductor devices in which a uniaxial strain component may be obtained in the channel regions of semiconductor fins by providing a channel semiconductor material in a strained state, at least on a top surface of the semiconductor fins. For example, a silicon/germanium material may be provided on the basis of epitaxial growth techniques on a silicon-based material, which may subsequently be patterned into a semiconductor fin so that, due to the superior length to width ratio, a desired strain component along the length direction of the fin may be substantially preserved, while a non-desired strain component along the width direction may be significantly relaxed. Since also the channel portion of the semiconductor fin has a greater length compared to its width, a desired high strain component along the current flow direction may also be preserved in the channel portion of the semiconductor fins. In other cases, additionally, the sidewall surface areas of the base material may also be used as a template material for depositing thereon a strained semiconductor material, thereby providing superior flexibility in adjusting the final strain in the channel region and the overall electronic characteristics.

The particular embodiments disclosed above are illustrative only, as the invention may be modified and practiced in different but equivalent manners apparent to those skilled in the art having the benefit of the teachings herein. For example, the process steps set forth above may be performed in a different order. Furthermore, no limitations are intended to the details of construction or design herein shown, other than as described in the claims below. It is therefore evident that the particular embodiments disclosed above may be altered or modified and all such variations are considered within the scope and spirit of the invention. Accordingly, the protection sought herein is as set forth in the claims below.

What is claimed:

1. A method, comprising:
providing a strained semiconductor channel material on a semiconductor fin that is formed above a substrate of a semiconductor device, said semiconductor fin having a length and a width, said length and said width resulting in a substantially uniaxial strain of said semiconductor channel material at least in a central portion of said semiconductor fin;
forming a gate electrode structure on said at least a central portion of said semiconductor fin, said gate electrode structure being configured to control current flow in at least said central portion of said semiconductor fin; and
forming drain and source areas adjacent to said at least a central portion.

2. The method of claim 1, wherein providing said strained semiconductor channel material comprises forming said strained semiconductor channel material on a semiconductor layer and forming said fin from said semiconductor layer that comprises said strained semiconductor channel material.

3. The method of claim 2, further comprising forming a further semiconductor channel material on said fin, wherein said further semiconductor channel material has the same type of strain as said strained semiconductor channel material.

4. The method of claim 1, wherein providing said strained semiconductor channel material comprises forming said strained semiconductor channel material on said fin after forming said fin from a semiconductor layer.

5. The method of claim 1, further comprising forming a second fin without said strained semiconductor channel material.

6. The method of claim 1, wherein said strained semiconductor channel material is formed with a thickness of approximately 5-12 nm.

7. The method of claim 3, wherein said second strained semiconductor channel material is formed with a thickness of approximately 1-6 nm.

8. The method of claim 1, further comprising forming at least one further fin from said semiconductor layer and forming a second strained semiconductor channel material on said second fin, wherein said second strained semiconductor channel material has a different type of strain compared to said strained semiconductor channel material.

9. A method of forming a transistor of a semiconductor device, the method comprising:
forming an elongated semiconductor body from a semiconductor base material;
providing a strained semiconductor material on at least one surface of said elongated semiconductor body; and
forming a gate electrode structure above said elongated semiconductor body, said gate electrode structure comprising a gate electrode for controlling a channel region of said elongated semiconductor body.

10. The method of claim 9, further comprising forming drain and source regions in a semiconductor region so as to connect to said channel region.

11. The method of claim 10, wherein providing a strained semiconductor material comprises forming a strained semiconductor material on said semiconductor base material prior to forming said elongated semiconductor body.

12. The method of claim 11, wherein providing a strained semiconductor material further comprises forming a further strained semiconductor material on said elongated semiconductor body after forming said elongated semiconductor body.

13. The method of claim 9, wherein providing a strained semiconductor material on said elongated semiconductor body comprises forming a strained semiconductor material on each surface area of said elongated semiconductor body.

14. The method of claim 9, wherein forming said elongated semiconductor body comprises selecting a length of said elongated semiconductor body and a thickness of said strained semiconductor material so as to increase charge carrier mobility compared to said semiconductor base material.

15. The method of claim 9, wherein providing said strained semiconductor material comprises forming said strained semiconductor material selectively above a first active region and masking a second active region.

16. The method of claim 9, wherein providing said strained semiconductor material comprises depositing said strained semiconductor material with a thickness of approximately 12 nm or less.

17. A semiconductor device, comprising:
a semiconductor fin comprising a semiconductor base material and a strained semiconductor channel material formed at least on one surface of said semiconductor fin; and
a gate electrode structure formed adjacent to and around said semiconductor fin, said gate electrode structure being configured to control a current flow through said semiconductor fin.

18. The semiconductor device of claim 17, wherein said strained semiconductor channel material has a thickness of approximately 1-12 nm.

19. The semiconductor device of claim 17, wherein said strained semiconductor channel material is formed on sidewalls of said semiconductor fins.

20. The semiconductor device of claim 17, wherein a thickness of said strained semiconductor channel material on said sidewalls is less than a thickness of said strained semiconductor channel material formed on a top surface of said semiconductor base material.
